(19) United States
(12) Patent Application Publication
(10) Pub. No.: US 2010/0268498 A1
(43) Pub. Date: Oct. 21, 2010

(54) SYSTEM AND METHOD FOR TESTING SIGNALS OF ELECTRONIC COMPONENTS

(75) Inventors: SHEN-CHUN LI, Tu-Cheng (TW); SHOU-KUO HSU, Tu-Cheng (TW)

Correspondence Address: Altis Law Group, Inc.;ATTN: Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/603,666

(22) Filed: Oct. 22, 2009

(30) Foreign Application Priority Data
Apr. 16, 2009 (CN) 200910301601.5

(51) Int. Cl. G01R 13/00; G06F 19/00

(52) U.S. Cl. 702/67

(57) ABSTRACT

A method for testing signals of electronic components. The method sends a positioning command to a control computer through a switch, so as to drive a probe holder of a mechanical arm to position probes of the oscilloscope on a position of the electronic component. The method further receives measured data collected by the oscilloscope, and compares the measured data with preset standard values to determine if the measured data is acceptable.

### BACKGROUND

1. Technical Field

Embodiments of the present disclosure relate to test technology, and particularly to a system and method for testing signals of electronic components.

2. Description of Related Art

Signal testing of components on the electronic device (e.g., a motherboard) is an important phase in the manufacturing process and is closely interrelated to product quality. Currently, the signal testing of the components on the electronic devices are manually operated using an oscilloscope. In recent years, a mechanical arm has been used to control a movement of an object automatically. Therefore, prompt and accurate test of signals of the components on the electronic device using the mechanical arm is desirable.

### BRIEF DESCRIPTION OF THE DRAWINGS

FIG. 1 is a schematic diagram of one embodiment of a test computer comprising a system for testing signals of electronic components;

FIG. 2 is a block diagram of one embodiment of a test computer comprising a signal testing program; and

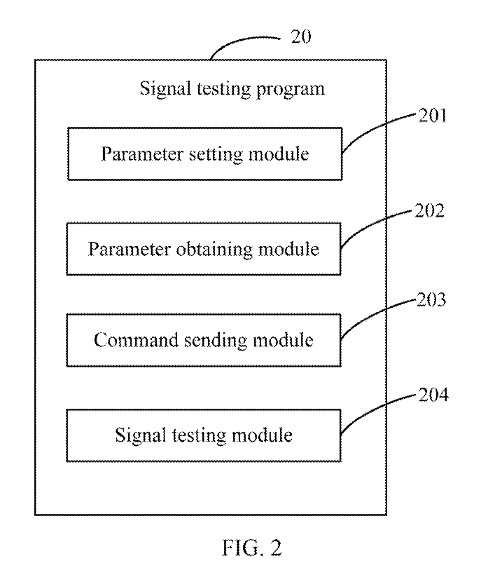

FIG. 3 is a flowchart of one embodiment of a method for testing signals of electronic components.

### DETAILED DESCRIPTION

All of the processes described below may be embodied in, and fully automated via, functional code modules executed by one or more general purpose computers or processors. The code modules may be stored in any type of readable medium or other storage device. Some or all of the methods may alternatively be embodied in specialized hardware. Depending on the embodiment, the readable medium may be a hard disk drive, a compact disc, a digital video disc, or a tape drive.

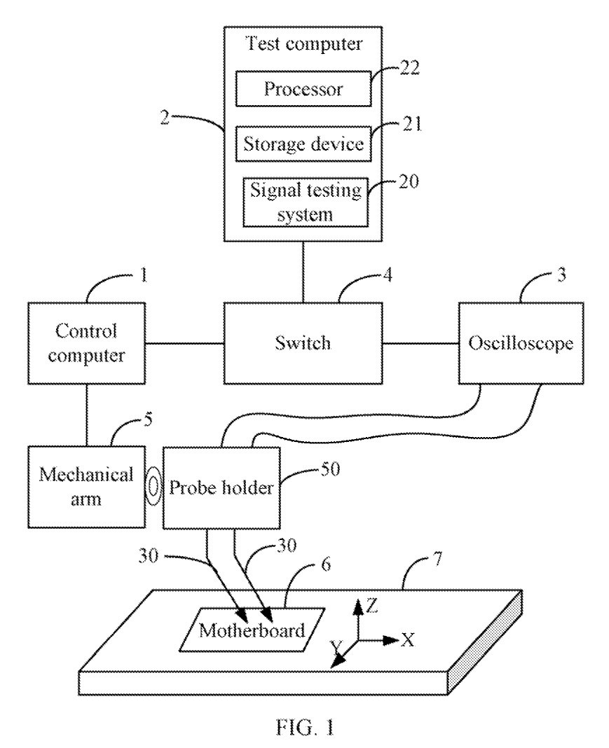

FIG. 1 is a schematic diagram of one embodiment of a test computer 2 comprising a signal testing system 20. In one embodiment, the test computer 2 is connected to a control computer 1 and an oscilloscope 3 through a switch 4. The control computer 1 is further connected to a mechanical arm 5. A probe holder/rack 50 is configured at an end of the mechanical arm 5. Probes 30 of the oscilloscope 3 are held by the probe holder 50. Referring to FIG. 1, the signal testing system 20 may be used to test signals of components of an electronic device 6 by sending a positioning command to the control computer 1 through the switch 4 to drive the probes 30 to an electronic component (e.g., a slot on the electronic device 6). The oscilloscope 3 collects measured data on the electronic component and sends the measured data to the test computer 2 through the switch 4. The measured data are compared with preset standard values, so as to determine if the measured data are acceptable. A detailed description will be given in the following paragraphs.

The test computer 2 further includes a storage device 21 for storing data, such as test parameters of each component in the electronic device 6. In one embodiment, the test parameters of the electronic component may include coordinates of the electronic component on the electronic device 6, a signal sequence of the electronic component, test items of each signal in the signal sequence, a standard value of each test item, and a preset storing path to store measured data of the electronic component.

The electronic device 6 is positioned on a test platform 7. In one embodiment, the electronic device 6 may be a motherboard or a printed circuit board (PCB).

In one embodiment, the signal testing system 20 includes a parameter setting module 201, a parameter obtaining module 202, a command sending module 203, and a signal testing module 204. In one embodiment, the modules 201-204 comprise one or more computerized instructions that are stored in the storage device. A processor 22 of the test computer 2 executes the computerized instructions to implement one or more operations of the test computer 2.

The parameter setting module 201 sets the test parameters of the electronic component and stores the test parameters in the storage device 21. As mentioned above, the test parameters may include the coordinates of the electronic component, the signal sequence of the electronic component, the test items of each signal in the signal sequence, the standard value of each test item, and the preset storing path to store test data of the electronic component. In one embodiment, the signal sequence of the electronic component may include a voltage signal, a periodic signal, and a frequency signal. For example, the test items of the voltage signal include an overshoot value of the voltage signal, an undershoot value of the voltage signal, a slew rate of the voltage signal, a rise time of the voltage signal, a fall time of the voltage signal, and a duty cycle distortion of the voltage signal.

The parameter obtaining module 202 reads the signal sequence of the electronic component and the test items of each signal in the signal sequence when the test starts.

The command sending module 203 sends a positioning command to the control computer 1 according to the coordinates of the electronic component on the electronic device 6. A detailed description is as follows. Firstly, the command sending module 203 calculates a scalar value between the coordinates of the electronic component and an origin of a coordinate system. In one embodiment, the origin is a center point of the electronic device 6, and an initial position of the probe holder 50 is positioned at the origin. Then, the command sending module 203 sends the positioning command to the control computer 1, where the positioning command includes the scalar value.

The control computer 1 drives the probe holder 50 of the mechanical arm 5 to position the probes 30 to a position of the electronic component according to the positioning command For example, supposing the coordinate of the electronic component is (10, 12), where a unit is one millimeter. After receiving the positioning command, the control computer 1 drives the probe holder 50 to move the probes 30 along an X-axis of the coordinate system with a distance of 10 millimeters, then move the probes 30 along a Y-axis of the coordinate system with a distance of 12 millimeters, so as to position the probes 30 to the position of the electronic component.

The signal testing module 204 controls the oscilloscope 3 to test each signal in sequence, reads measured data of each test item collected by the oscilloscope 3, and stores the measured data in the preset storing path (e.g., D:\Motherboard\Test).

The signal testing module 204 further compares the measured data of each test item with the standard value of the test item, so as to determine if the measured data of each test item is acceptable. For example, supposing the standard value of the rise time of the voltage signal is [0.1, 0.5], where a unit is one second. If the test data of the rise time obtained by the oscilloscope 3 is 0.08 seconds, the signal testing module 204 determines the measured data is not acceptable.

The signal testing module 204 further determines if all the signals in the signal sequence have been tested. If any signal in the signal sequence has not been tested, the signal testing module 204 tests the next signal in the signal sequence. If all the signals in the signal sequence have been tested, the signal testing module 204 collects all the measured data and the determined results, and stores all the measured data and the determined results in the preset storing path.

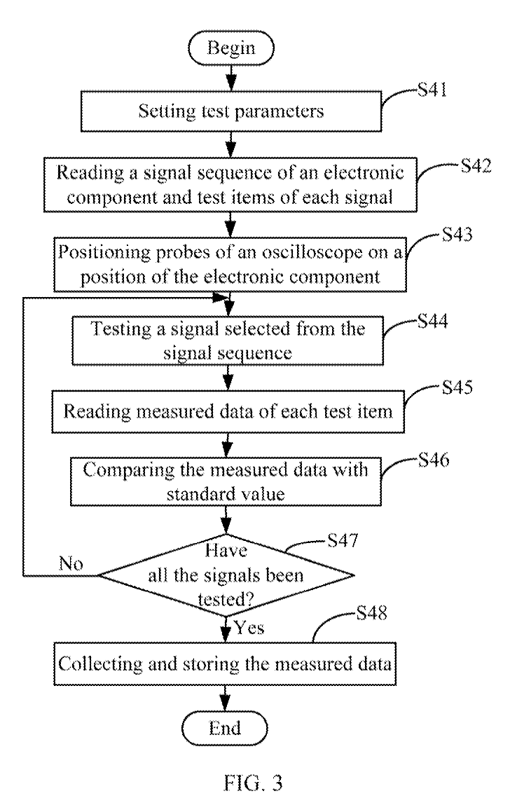

FIG. 3 is a flowchart of one embodiment of a method for testing signals of electronic components. Depending on the embodiment, additional blocks may be added, others removed, and the ordering of the blocks may be changed.

In block S41, the parameter setting module 201 sets test parameters of the electronic component and stores the test parameters in the storage device 21.

In block S42, the parameter obtaining module 202 reads the signal sequence of the electronic component and the test items of each signal in the signal sequence.

In block S43, the command sending module 203 sends a positioning command to the control computer 1 according to the coordinates of the electronic component on the electronic device 6. A detailed description is given in paragraph [0013].

Then, in block S43, the control computer 1 drives the probe holder 50 of the mechanical arm 5 to position the probes 30 to a position of the electronic component according to the positioning command.

In block S44, the signal testing module 204 controls the oscilloscope 3 to test a signal selected from the signal sequence in sequence.

In block S45, the signal testing module 204 reads measured data of each test item of the selected signal collected by the oscilloscope 3, and stores the measured data in the preset storing path.

In block S46, the signal testing module 204 compares the measured data of each item with the standard value of the test item, so as to determine if the measured data of each test item is acceptable.

In block S47, the signal testing module 204 further determines if all the signals in the signal sequence have been tested. If any signal in the signal sequence has not been tested, the procedure returns to block S44. Otherwise, the procedure goes to block S48 if all the signals in the signal sequence have been tested. For example, supposing m represents a total number of the signals in the signal sequence to be tested, i represents a current number of test. For the purpose of illustration, an initial value of i equals one. If i is less than m, i is evaluated as i+1 (i=i+1), the procedure returns to the block S44. If i is greater than or equal to m, the procedure goes to block S48.

In block S48, the signal testing module 204 collects all the measured data and the determined results, and stores all the measured data and the determined results in the preset storing path.

In this embodiment, for the purpose of illustration, only one electronic component on the electronic device 6 is tested. In other embodiments, if the electronic device 6 includes two or more electronic components to be tested, the command sending module 203 further obtains a coordinate of a next electronic component when a current electronic component has been tested, and calculates a scalar value between the coordinates of the next electronic component and coordinates of the current electronic component. Then, the command sending module 203 sends a positioning command to the control computer 1, where the positioning command includes the scalar value between the coordinates of the next electronic component and the coordinates of the current electronic component. Thus, the control computer 1 drives the probe holder 50 to position the probes 30 on a position of the next electronic component according to the positioning command.

It should be emphasized that the above-described embodiments of the present disclosure, particularly, any embodiments, are merely possible examples of implementations, merely set forth for a clear understanding of the principles of the disclosure. Many variations and modifications may be made to the above-described embodiment(s) of the disclosure without departing substantially from the spirit and principles of the disclosure. All such modifications and variations are intended to be included herein within the scope of this disclosure and the present disclosure and protected by the following claims.

What is claimed is:

1. A signal testing system for testing signals of an electronic component, the signal testing system electronically connected to a control computer and an oscilloscope through a switch, and further electronically being connected to a mechanical arm, the signal testing system comprising:
a parameter setting module operable to set test parameters of the electronic component, the test parameters comprise coordinates of the electronic component on the electronic device, a signal sequence of the electronic component, test items of each signal in the signal sequence, a standard value of each test item, and a preset storing path to store test data of the electronic component;
a parameter obtaining module operable to read the signal sequence of the electronic component and the test items of each signal in the signal sequence;
a command sending module operable to send a positioning command to the control computer according to the coordinates of the electronic component on the electronic device, so as to drive a probe holder of the mechanical arm to position probes of the oscilloscope to a position of the electronic component;
a signal testing module operable to control the oscilloscope to test each signal in the signal sequence, and read measured data of each test item collected by the oscilloscope;
the signal testing module further operable to compare the measured data of each test item with the standard value of the test item, so as to determine if the measured data of each test item is acceptable;
the signal testing module further operable to collect all the measured data and the determined results if all the signals in the signal sequence have been tested, and storing all the measured data and the determined results in the preset storing path; and
at least one processor to execute the parameter setting module, the parameter obtaining module, the command sending module, and the signal testing module.

2. The system according to claim 1, wherein the signals in the signal sequence comprise a voltage signal, a periodic signal, and a frequency signal.

3. The system according to claim 1, wherein the command sending module sends a positioning command to the control computer according to the coordinates of the electronic component on the electronic device by:
calculating a scalar value between the coordinates of the electronic component and an origin of a coordinate system, wherein the origin of the coordinate system is positioned at a center point of the electronic device, and an initial position of the probe holder is positioned at the origin of the coordinate system; and
sending the positioning command to the control computer, wherein the positioning command comprises the scalar value between the coordinates of the electronic component and the origin of the coordinate system.

4. The system according to claim 1, wherein the command sending module further operable to:
obtain coordinates of a next electronic component to be tested when a current electronic component has been tested if the electronic device comprises two or more electronic components to be tested, and calculate a scalar value between the coordinates of the next electronic component and coordinates of the current electronic component; and
send a positioning command to the control computer, wherein the positioning command comprises the scalar value between the coordinates of the next electronic component and the coordinates of the current electronic component.

5. The system according to claim 1, wherein the electronic device is a motherboard or a printed circuit board.

6. A computer-implemented method for testing signals of an electronic component, the method comprising:
setting test parameters of the electronic component and storing the test parameters in a storage of a test computer, the test parameters comprising coordinates of the electronic component on the electronic device, a signal sequence of the electronic component, test items of each signal in the signal sequence, a standard value of each test item, and a preset storing path to store test data of the electronic component;
reading the signal sequence of the electronic component and the test items of each signal in the signal sequence by the test computer;
sending a positioning command from the test computer to a control computer through a switch according to the coordinates of the electronic component on the electronic device;
driving a probe holder of a mechanical arm by the control computer according to the positioning command, so as to position probes of an oscilloscope to a position of the electronic component;
controlling the oscilloscope to test each signal in the signal sequence;
returning measured data of test items of each test signal collected by the oscilloscope to the test computer through the switch;
comparing the measured data of each test item with the standard value of the test item, so as to determine if the measured data of each test item is acceptable; and
collecting all the measured data and the determined results if all the signals in the signal sequence have been tested, and storing all the measured data and the determined results in the preset storing path.

7. The method according to claim 6, wherein the signals in the signal sequence comprise a voltage signal, a periodic signal, and a frequency signal.

8. The method according to claim 6, wherein sending a positioning command from the test computer to a control computer through a switch according to the coordinates of the electronic component on the electronic device comprises:
calculating a scalar value between the coordinates of the electronic component and an origin of a coordinate system, wherein the origin of the coordinate system is positioned at a center point of the electronic device, and an initial position of the probe holder is positioned at the origin of the coordinate system; and
sending the positioning command to the control computer, wherein the positioning command comprises the scalar value between the coordinates of the electronic component and the origin of the coordinate system.

9. The method according to claim 6, further comprising:
obtaining coordinates of a next electronic component to be tested when a current electronic component has been tested if the electronic device comprises two or more electronic components to be tested, and calculating a scalar value between the coordinates of the next electronic component and coordinates of the current electronic component; and
sending a positioning command to the control computer, wherein the positioning command comprises the scalar value between the coordinates of the next electronic component and the coordinates of the current electronic component.

10. The method according to claim 6, wherein the electronic device is a motherboard or a printed circuit board.

11. A storage medium having stored thereon instructions that, when executed by a processor of a computer, cause the processor to perform a method for testing signals of an electronic component, the method comprising:
setting test parameters of the electronic component and storing the test parameters in a storage of a test computer, the test parameters comprising coordinates of the electronic component on the electronic device, a signal sequence of the electronic component, test items of each signal in the signal sequence, a standard value of each test item, and a preset storing path to store test data of the electronic component;
reading the signal sequence of the electronic component and the test items of each signal in the signal sequence by the test computer;
sending a positioning command from the test computer to a control computer through a switch according to the coordinates of the electronic component on the electronic device;
driving a probe holder of a mechanical arm by the control computer according to the positioning command, so as to position probes of an oscilloscope to a position of the electronic component;
controlling the oscilloscope to test each signal in the signal sequence;
returning measured data of test items of each test signal collected by the oscilloscope to the test computer through the switch;
comparing the measured data of each test item with the standard value of the test item, so as to determine if the measured data of each test item is acceptable; and
collecting all the measured data and the determined results if all the signals in the signal sequence have been tested, and storing all the measured data and the determined results in the preset storing path.

12. The storage medium according to claim 11, wherein the signals in the signal sequence comprise a voltage signal, a periodic signal, and a frequency signal.

13. The storage medium according to claim 11, wherein sending a positioning command from the test computer to a control computer through a switch according to the coordinates of the electronic component on the electronic device comprises:
calculating a scalar value between the coordinates of the electronic component and an origin of a coordinate system, wherein the origin of the coordinate system is positioned at a center point of the electronic device, and an initial position of the probe holder is positioned at the origin of the coordinate system; and
sending the positioning command to the control computer, wherein the positioning command comprises the scalar value between the coordinates of the electronic component and the origin of the coordinate system.

14. The storage medium according to claim 11, wherein the method further comprises:
obtaining coordinates of a next electronic component to be tested when a current electronic component has been tested if the electronic device comprises two or more electronic components to be tested, and calculating a scalar value between the coordinates of the next electronic component and coordinates of the current component; and
sending a positioning command to the control computer, wherein the positioning command comprises the scalar value between the coordinates of the next electronic component and the coordinates of the current electronic component.

15. The storage medium according to claim 11, wherein the electronic device is a motherboard or a printed circuit board.

16. The storage medium according to claim 11, wherein the medium is selected from the group consisting of a hard disk drive, a compact disc, a digital video disc, and a tape drive.
